(19) United States
(12) Patent Application Publication
(10) Pub. No.: US 2005/0045968 A1
(43) Pub. Date: Mar. 3, 2005

(54) Semiconductor device with borderless contact structure and method of manufacturing the same

(76) Inventors: Sung-Un Kwean, Gyeonggi-do (KR); Jae-Seung Hwang, Suwon-si (KR)

Correspondence Address: F. CHAU & ASSOCIATES, LLC, 130 WOODBURY ROAD, WOODBURY, NY, 11797, US

(21) Appl. No.: 10/939,266

(22) Filed: Sep. 10, 2004

Related U.S. Application Data
(62) Division of application No. 10/172,354, filed on Jun. 14, 2002.

(30) Foreign Application Priority Data
Jun. 19, 2001 (KR) 2001-34789

(51) Int. Cl. H01L 21/8238; H01L 29/76; H01L 29/94

(52) U.S. Cl. 257/408

(57) ABSTRACT

A semiconductor device comprising a borderless contract structure and a method of manufacturing the same. An etch-protecting layer is formed on a semiconductor substrate having gate electrodes formed on an active area of the substrate. Spacers are formed on the etch-protecting layer, and removed after performing a source/drain ion-implantation process to secure a region for forming a contact hole between the gate electrodes. After sequentially forming an etch-stopping layer and an insulating interlayer on a resultant structure, the etch-stopping layer and the insulating interlayer are etched to form the first contact hole which exposes a surface of the semiconductor substrate between gate electrodes and a second contact hole for the borderless contact which exposes the surface of the semiconductor substrate adjacent to the field oxide layer and a portion of a surface of the field oxide layer.

### CROSS-REFERENCE TO RELATED APPLICATION

This application claims priority to Korean Patent Application No. 2001-34789 filed on Jun. 19, 2001.

### BACKGROUND

1. Technical Field

The present invention relates to a semiconductor device and a method of manufacturing the same, and more particularly to a semiconductor device comprising a borderless contact structure and a method of manufacturing the same.

2. Description of Related Art

In a semiconductor device, a contact is used to connect isolated areas with each other in the semiconductor substrate by using a high conductive thin film. Because a contact is formed to have an align margin and a device isolating margin, the contact requires a relatively large space. Consequently, the contact design is a main factor in determining the size of a memory cell of a semiconductor device.

Recently, in semiconductor devices having a design rule of less than 0.12 μm, a lightly doped drain (LDD) structure has been used to prevent a short channel effect of a transistor. The LDD structure requires spacers formed on the sidewalls of a gate electrode such that highly concentrated source/drain areas are spaced apart from the gate electrode by a predetermined distance.

Further, since a margin for forming a contact hole in an active area of a transistor is reduced in the semiconductor device, a borderless contact process has been introduced to form a contact on both the active area and a field area. The borderless contact process forms the contact on the active area and extends the contact to the field area in such a manner that the size of the contact is not reduced while maintaining the distance between the gate electrode of the transistor and the contact.

One exemplary borderless contact process comprises the step of etching an insulating interlayer formed on a silicon substrate to expose a portion of a field oxide layer and a surface of the silicon substrate adjacent to the field oxide layer. This process, however, creates a recess in the exposed field oxide layer. If the depth of the recess is deeper than the depth of a source/drain junction of an active area or closer to a junction boundary, a direct contact route is created between the contact and the silicon substrate, so leakage current occurs.

Even when a contact hole is thinner than the source/drain junction of the active area, if the contact hole is formed adjacent to the source/drain junction, a barrier layer used for forming a following contact hole is reacted with silicon so that leakage current may occur. For example, when a barrier layer comprising Ti/TiN is heat-treated, silicon in the source/drain area is reacted with Ti/TiN, thereby forming a silicide layer, which acts as a conductive layer. This silicide layer causes the leakage current.

An etch-stopping layer may be formed when the contact is etched to prevent the recess creation on the surface of the field oxide layer during the borderless contact process. FIGS. 1A to 1D are sectional views illustrating a conventional method for forming a contact hole of a semiconductor device by using a borderless contact process.

Referring to FIG. 1A, a mask pattern (not shown) is formed on a semiconductor substrate 10. By using the mask pattern as an etch mask, the semiconductor substrate 10 is etched to form a trench. An oxide film is deposited on the entire surface of the semiconductor substrate 10 to fill the trench via a chemical vapor deposition (CVD) process. An etch-back process or a chemical mechanical polishing (CMP) process is performed until the surface of the mask pattern is exposed, thereby forming a field oxide layer 12 only in the trench. As a result, the semiconductor substrate 10 is divided into an active area and a field area by the field oxide layer 12. Then, the mask pattern is removed.

A gate oxide layer 14 is formed on the active area of the semiconductor substrate 10 and a gate electrode 15 of a transistor is formed on the gate oxide layer 14. The gate electrode 15 has a polycide structure comprising a polysilicon layer 16 doped with impurities and a metal silicide layer 18 stacked on the polysilicon layer 16. Then, a first impurity 20 is ion-implanted by using the gate electrodes 15 as a mask, so that lightly doped source/drain areas 22 (LDD areas) are formed in the semiconductor substrate 10 on both sides of the gate electrode 15.

Referring to FIG. 1B, a nitride film, such as a silicon nitride (SiN) film, is deposited on the entire surfaces of the gate electrodes 15 and the semiconductor substrate 10. An etch-back process is performed with respect to the nitride film so that spacers 24 are formed on both sidewalls of the gate electrode 15. Then, a second impurity 26 is ion-implanted by using the gate electrodes 15 and the spacers 24 as a mask, thereby forming highly doped source/drain areas 28 in the surface portions (i.e., active area) of the semiconductor substrate 10 on both sides of the spacers 24.

Referring to FIG. 1C, a nitride film, such as a silicon nitride (SiN) film is deposited on the entire surfaces of the spacers 24, the gate electrodes 15 and the semiconductor substrate 10 to a thickness in the range of about 300 to about 500 [symbol] , thereby forming an etch-stopping layer 30. The etch-stopping layer 30 protects the field oxide layer 12 during a following borderless contact hole etching process.

Referring to FIG. 1D, an oxide film, such as BPSG (Boro-PhosphoSilicate glass) film or PSG (Phosphosilicate glass) film, is deposited on the etch-stopping layer 30, thereby forming an insulating interlayer 32. A photoresist pattern (not shown) is formed on the insulating interlayer 32 through a photo process. The insulating interlayer 32 and the etch-stopping layer 30 are sequentially dry-etched by using the photoresist pattern as an etching mask, thereby forming a first contact hole 34a and a second contact hole 34b. The first contact hole 34a exposes a surface portion of the semiconductor substrate 10 between the gate electrodes 15. The second contact hole 34b exposes a surface portion of the semiconductor substrate 10 adjacent to the field oxide layer 12 and a surface portion of the field oxide layer 12.

As the semiconductor devices are highly integrated, the space critical dimension (CD) between the active area and the field area and the space critical dimension between the gate electrodes 15 are reduced in a semiconductor device having a design rule less than 0.12 μm.

However, the etch- stopping layer 30 for the borderless contact, in the conventional method, has to have a thickness greater than 300 μm to prevent a recess being formed on the field oxide layer 12 when the LDD spacers 24 are formed on the sidewalls of the gate electrode 15. The space critical dimension between the gate electrodes 15 becomes narrow, so the space between gate electrodes 15 is filled with the etch-stopping layer 30 (refer to “A” in FIG. 1C). That is, the space critical dimension between gate electrodes 15 is reduced by the spacers 24 and the etch-stopping layer 30, so it is difficult to sufficiently achieve the bottom critical dimension of the first contact hole 34a formed between the gate electrodes 15. Accordingly, the etch-stopping layer 30 is not completely removed, but remains in the space between the gate electrodes 15 during a following contact hole etching process. Therefore, a failure occurs, such as an unopened portion (refer to “B” of FIG. 1D) of a first contact hole 34a.

The insulating interlayer 32 and the etch-stopping layer 30 may be etched away until the surface of the semiconductor substrate 10 between the gate electrodes 15 is completely exposed, to solve the not-open problem of the first contact hole 34a. In this case, however, the field oxide layer 12 is over-etched by a borderless contact hole (i.e., a second contact hole 34b) formed at the boundary between the field area and the active area.

### SUMMARY OF THE INVENTION

It is an object of the present invention to provide a semiconductor device comprising a borderless contact structure that prevents an unopened contact hole from being formed on an active area between gate electrodes.

It is another object of the present invention to provide a method for forming a contact hole of a semiconductor device capable of preventing the formation of an unopened contact hole on an active area between gate electrodes.

According to one aspect of the present invention, a semiconductor device comprises a semiconductor substrate comprising an active area and a field area, the active and field area being divided by a field oxide layer, a plurality of gate electrodes formed on the active area of the semiconductor substrate, an etch-protecting layer formed on the gate electrodes and the semiconductor substrate, an etch-stopping layer stacked on the etch-protecting layer, and an insulating interlayer formed on the etch-stopping layer comprising a first contact hole passing through the etch-protecting layer and the etch-stopping layer to expose a surface of the semiconductor substrate formed between gate electrodes and a second contact hole passing through the etch-protecting layer and the etch-stopping layer to expose a surface of the semiconductor substrate adjacent to the field oxide layer and a portion of a surface of the field oxide layer, thereby forming a borderless contact between the active area and the field area, wherein the etch-protecting layer and the etch-stopping layer protect the gate electrodes and the semiconductor substrate during an etching process of forming the first and second contact holes such that an enlarged width between the gate electrodes is obtained without forming spacers between the gate electrodes.

According to another aspect of the present invention, a method for forming a contact hole of a semiconductor device comprises the steps of forming a plurality of gate electrodes on an active area of a semiconductor substrate, the semiconductor substrate comprising the active area and a field area divided by a field oxide layer, forming an etch-protecting layer on the gate electrodes and the semiconductor substrate, forming spacers on the etch-protecting layer formed on both sides of each gate electrode, the spacers comprising a material having an etch selectivity with respect to the etch-protecting layer, performing a source and drain ion-implantation process by using the gate electrodes on which the spares are formed as a mask, removing the spacers, forming an etch-stopping layer on the entire surface of the resultant structure, forming an insulating interlayer on the etch-stopping layer, and sequentially etching the insulating interlayer, the etch-stopping layer and the etch-protecting layer such that a first contact hole is formed to expose a surface of the semiconductor substrate between the gate electrodes and a second contact hole is formed to expose a surface of the semiconductor substrate adjacent to the field oxide layer and a portion of a surface of the field oxide layer, thereby forming a borderless contact between the field area and the active area.

According to further aspect of the present invention, a method for forming a contact hole of a semiconductor device comprises forming a plurality of gate electrodes on an active area of a semiconductor substrate, the semiconductor substrate comprising the active area and a field area divided by a field oxide layer, forming an etch-protecting layer on the gate electrodes and the semiconductor substrate, forming spacers on the etch-protecting layer formed on both sides of each gate electrode, the spacers comprising a material having an etch selectivity with respect to the etch-protecting layer, performing a source and drain ion-implantation process by using the gate electrodes on which the spares are formed as a mask, removing the spacers, forming an etch-stopping layer on the entire surface of the resultant structure, wherein the etch-stopping layer comprising a material similar to a material of the etch-protecting layer, forming an insulating interlayer on the etch-stopping layer, and sequentially etching the insulating interlayer, the etch-stopping layer and the etch-protecting layer, such that a first contact hole is formed to expose a surface of the semiconductor substrate between the gate electrodes and a second contact hole is formed to expose a surface of the semiconductor substrate adjacent to the field oxide layer and a portion of a surface of the field oxide layer, thereby forming a borderless contact between the field area and the active area.

Advantageously, spacers formed on the sidewalls of gate electrodes for achieving an LDD structure are removed after performing an ion-implantation process for highly (or heavily) doped source/drain, so that the bottom critical dimension of a first contact hole formed between the gate electrodes is sufficiently ensured. Therefore, the failure caused by the unopened portion of the first contact hole formed on an active area between the gate electrodes can be prevented.

These and other aspects, factors, and advantages of the present invention will become apparent from the following detailed description of preferred embodiments, which is to be read in conjunction with the accompanying figures

### BRIEF DESCRIPTION OF THE DRAWINGS

FIGS. 1A to 1D are sectional views showing a conventional method for forming a contact hole of a semiconductor device.

FIGS. 2A to 2I are sectional views showing a method for forming a contact hole of a semiconductor device according to one embodiment of the present invention.

FIGS. 3A and 3E are sectional views showing a method for forming a contact hole of a semiconductor device according to another embodiment of the present invention.

### DETAILED DESCRIPTION OF PREFERRED EMBODIMENTS

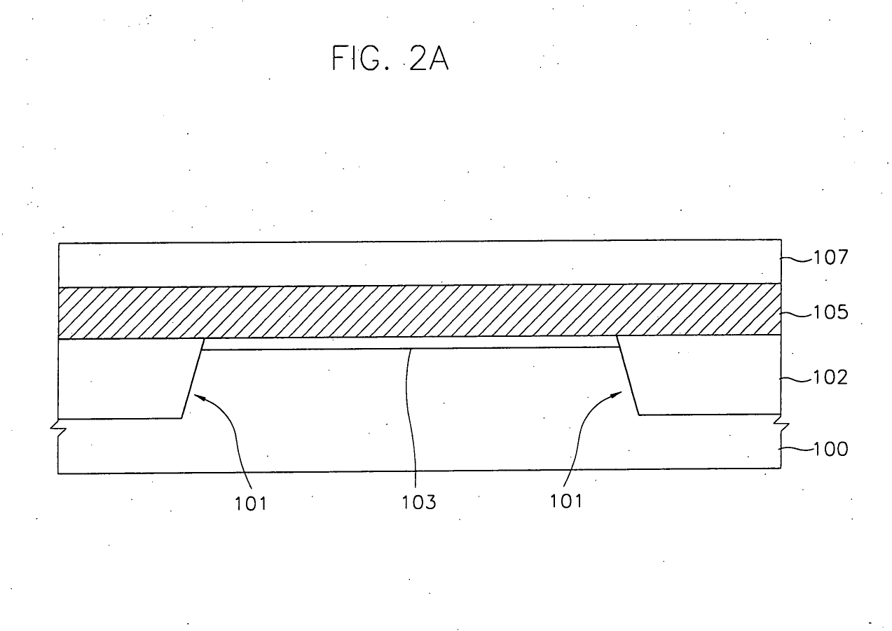

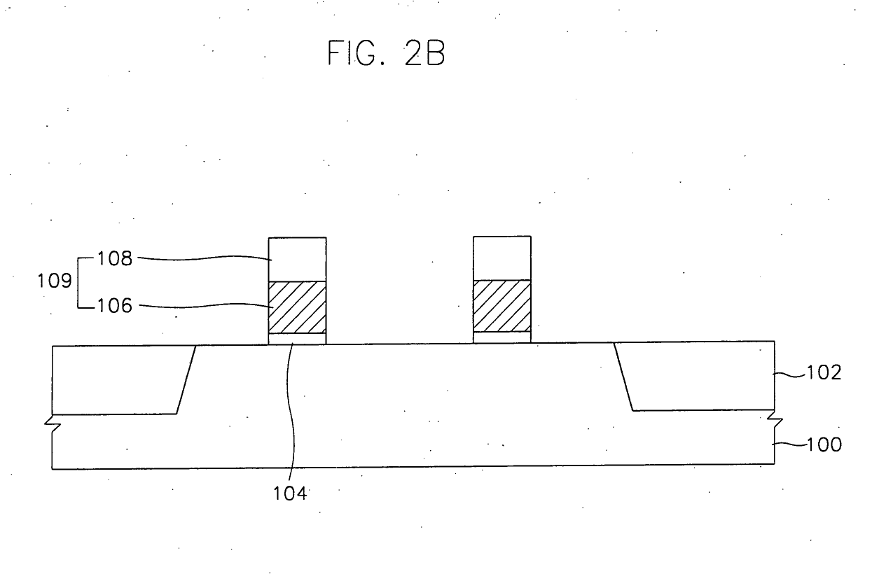

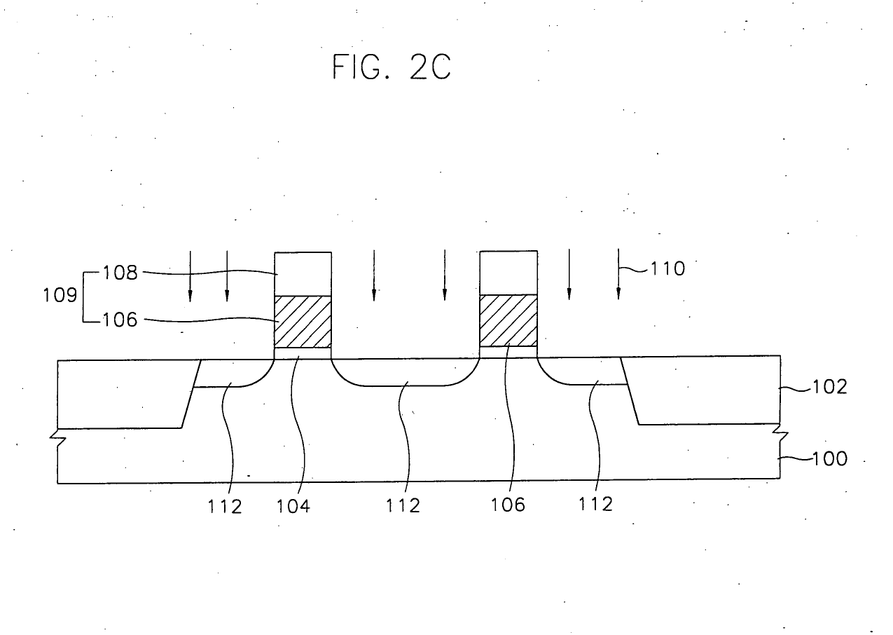

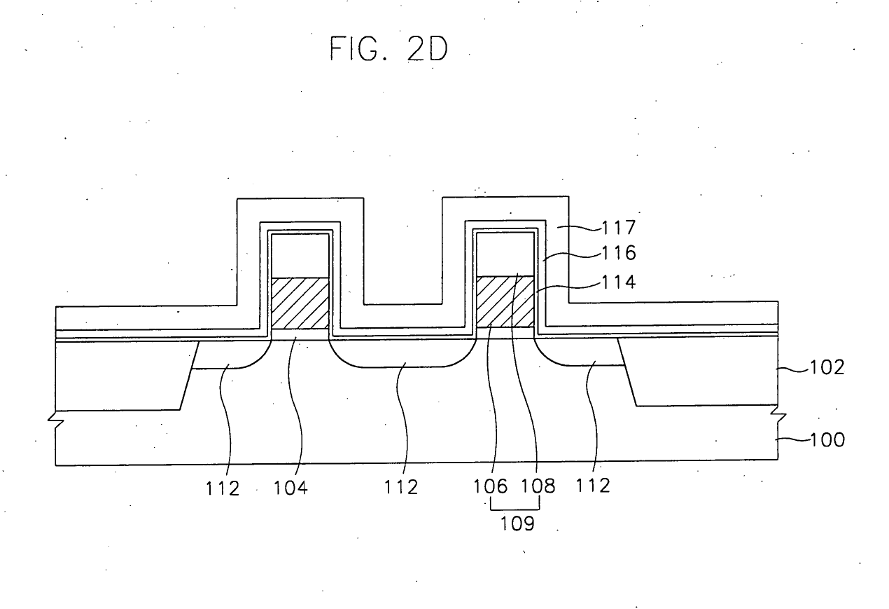

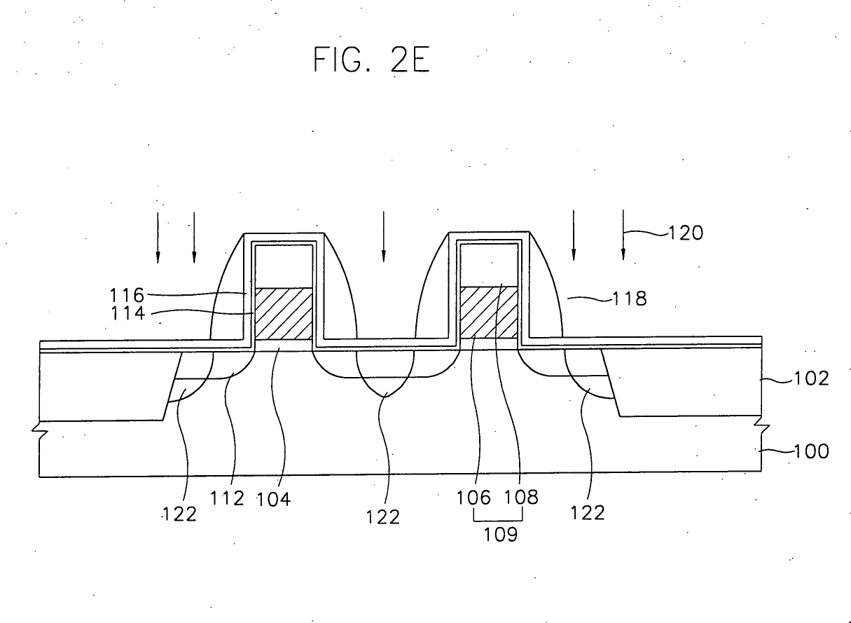

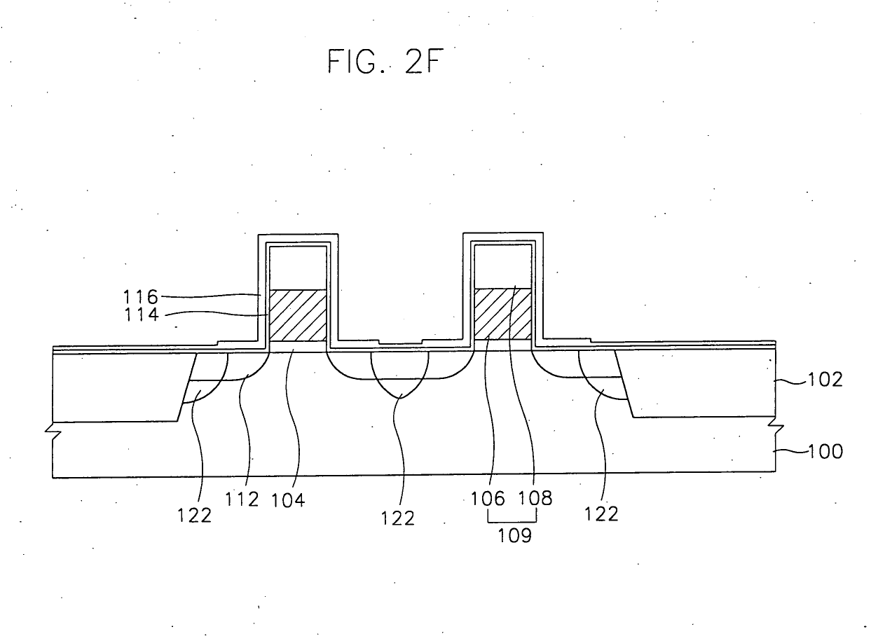

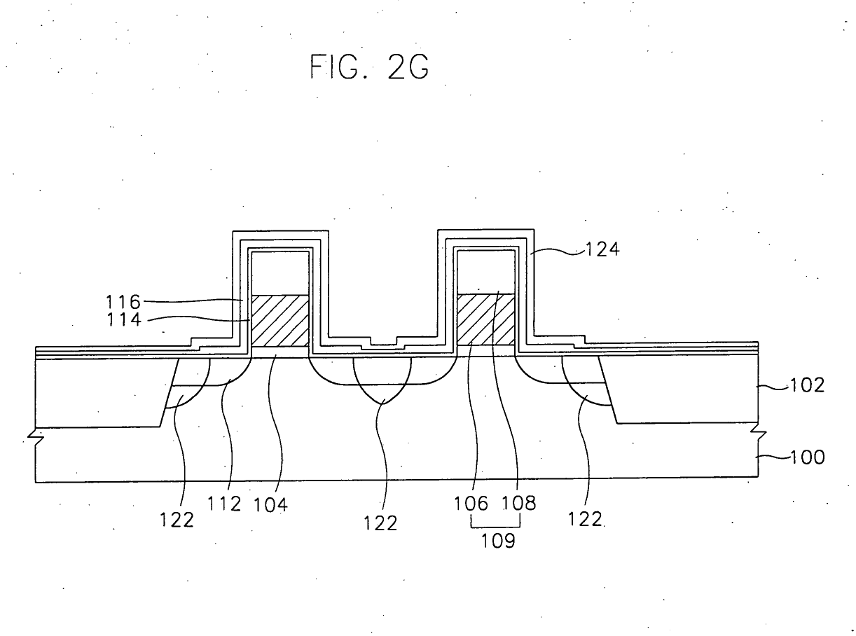

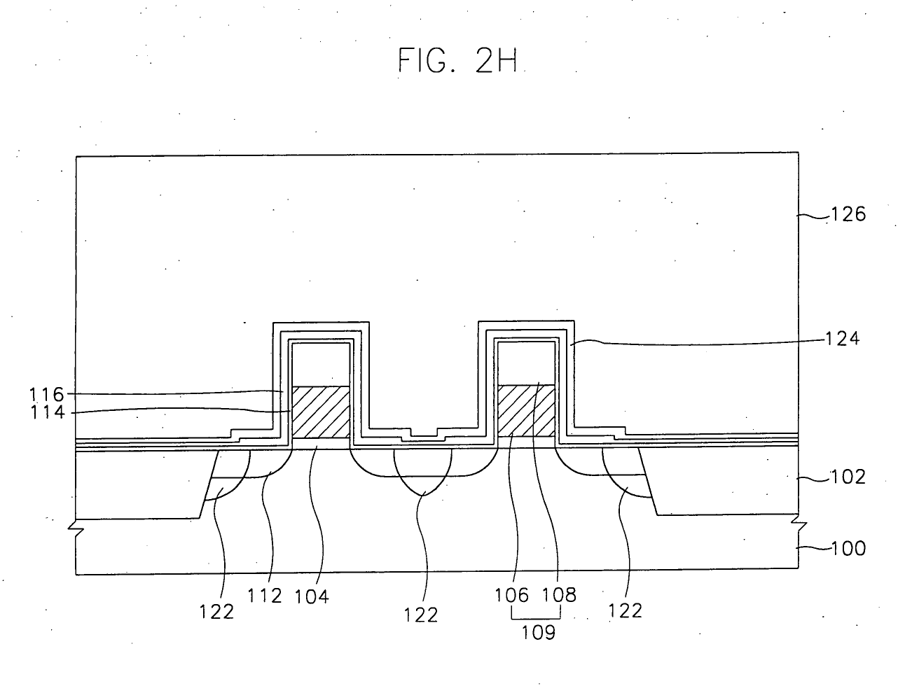

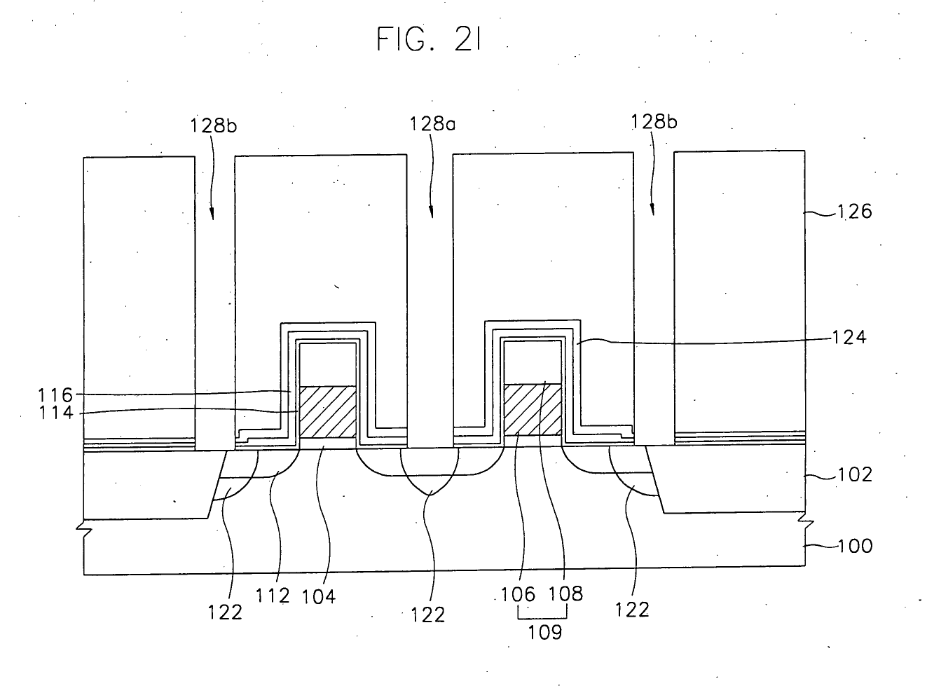

FIGS. 2A to 2I are sectional views showing a method for forming a contact hole of a semiconductor device according to one embodiment of the present invention.

FIG. 2A shows the step of forming a field oxide layer 102. A mask pattern (not shown), for example, a mask pattern comprising a pad oxide layer pattern and a nitride layer pattern stacked thereon is formed on a semiconductor substrate 100 to define a region for a field oxide layer. The semiconductor substrate 100 is etched in a predetermined depth by using the mask pattern as an etching mask, to thereby form a trench 101. The trench 101 generally has a depth about 4000 to 6000 Å from a surface of the semiconductor substrate 100 and a width about 4000 to 6000 Å. However, the depth or width of the trench 101 may be varied depending on the integration degree of the semiconductor device, a form of the active area to be divided or a resolution of a photo process.

A CVD process is performed to deposit an oxide film (not shown) on the entire surface of the resultant structure to completely fill up the trench 101. Preferably, a material having a superior gap-filling characteristic, such as USG, O₃-TEOS USG, or a high-density plasma (HDP) oxide film, is used as the oxide film.

A planarization process, such as an etch-back process or a CMP process, is performed until the surface of the upper nitride pattern of the mask pattern is exposed. Then, the mask pattern is removed. A field oxide layer 102 is formed in the trench 101 so that the semiconductor substrate 100 is divided into the active area and the field area.

A local oxidation of silicon (LOCOS) process or an improved LOCOS process may be used to form the field oxide layer 102, while a shallow trench isolation (STI) process is used to form the field oxide layer 102 in the present embodiment. A thermal oxidation process is performed to form an oxide layer 103 on the active area of the semiconductor substrate 100 in which the field oxide layer 102 is formed. A polysilicon layer 105 doped with impurities and a metal silicide layer 107 are sequentially deposited on the oxide layer 103 as a gate layer. A metal silicide may be deposited to form the metal silicide layer 107. The metal silicide may comprise tungsten silicide (WSiₓ), tantalum silicide (TaSi₂), molybdenum silicide (MoSi₂), or a combination thereof.

A nitride film such as silicon nitride (SiN) is deposited on the metal silicide layer 107 to a thickness of about 800 Å by using a low pressure chemical vapor deposition (LPCVD) method, thereby forming an anti-reflective layer (not shown). The anti-reflective layer prevents a light from being reflected from a lower substrate to allow a photoresist pattern to be easily formed during a following photolithography process.

FIG. 2B shows the step of forming a gate oxide layer 104 and a gate electrode 109. After forming a photoresist pattern (not shown) on the anti-reflective layer by using a photo process, the anti-reflective layer is patterned as a gate pattern by using the photoresist pattern as an etching mask. After removing the photoresist pattern, the metal silicide layer 107, the polysilicon layer 105 and the oxide layer 103 are sequentially dry-etched by using the patterned anti-reflective layer as an etching mask, thereby forming the gate oxide layer 104 and the gate electrode 109 on the active area of the semiconductor substrate 100. The anti-reflective layer is almost removed during the above etching process.

FIG. 2C shows the step of forming lightly doped source/drain areas 112. After forming the gate electrode 109, a first impurity 110 is ion-implanted by using the gate electrode 109 as a mask. As a result, the lightly doped source/drain areas 112, that is, LDD areas are formed in the surface of the semiconductor substrate 100 on both sides of the gate electrode 109.

A heat-treatment process is performed to activate the implanted ions and simultaneously, to compensate lattice defects of the semiconductor substrate 100 caused by the above ion-implantation.

FIG. 2D shows the step of forming a buffer layer 114, an etch-protecting layer 116 and an insulating layer 117. An oxide film is deposited to a thickness in the range of about 30 to about 100 Å on the entire surface of the semiconductor substrate 100 in which the gate electrode 109 and the lightly doped source/drain areas 112 are formed, thereby forming a buffer layer 114.

A nitride film such as SiN film, SiON film or BN film is deposited to a thickness in the range of about 50 to about 300 Å, preferably about 200 Å, to thereby form an etch-protecting layer 116 on the buffer layer 114. The buffer layer 114 prevents the etch-protecting layer 116 comprising the nitride from directly making contact with the semiconductor substrate 100. The etch-protecting layer 116 prevents the gate electrode 109, the semiconductor substrate 100 and the field oxide layer 102 from being damaged during the following LDD spacer removing process.

An insulating layer 117, which comprises a material having an etch selectivity to a material forming the etch-protecting layer 116 with respect to an any etching process, is formed on the etch-protecting layer 116 to a thickness in the range of about 500 to about 800 Å. Preferably, the insulating layer 117 comprises an oxide such as silicon oxide (SiO₂).

FIG. 2E shows the step of forming spacers 118 and highly doped source/drain areas 122. The insulating layer 117 is etched back to form the spacers 118 comprising oxide on both sidewalls of the gate electrode 109.

A second impurity 120 is ion-implanted by using the spacers 118 and the gate electrode 109 as a mask, thereby forming the highly doped source/drain areas 122 in the surface of the semiconductor substrate 100 on both sides of the spacers 118.

Preferably, the etch-protecting layer 116 formed on the semiconductor substrate 100 has a thickness, for example, a thickness no more than 200 Å, capable of reducing a blocking effect of the source/drain ion-implantation 120. For example, if the etch-protecting layer 116 has a thickness greater than 300 Å, the etch-protecting layer 116 blocks the source/drain ion to be implanted so that the saturation current of the transistor is reduced and the threshold voltage (Vth) is shifted, thereby deteriorating the electrical characteristics of the transistor. The heat-treatment process is performed to activate the implanted ions and simultaneously, to compensate lattice defects of the semiconductor substrate 100 caused by the above ion-implantation.

FIG. 2F shows the step of removing the spacers 118. After forming the highly doped source/drain areas 122, a wet etching process is performed by using etchant, such as HF or BOE (buffered oxide etchant), in which an etch selectivity of oxide with respect to nitride is 20:1, thereby removing only the spacers 118.

The etch-protecting layer 116 prevents the gate electrode 109, the active area of the semiconductor substrate 100 and the field oxide layer from being damaged during the wet etching process. When the spacers 118 are removed as described above, only the etch-protecting layer 116 remains on the upper surface and the side surface of the gate electrode 109 in a uniform thickness.

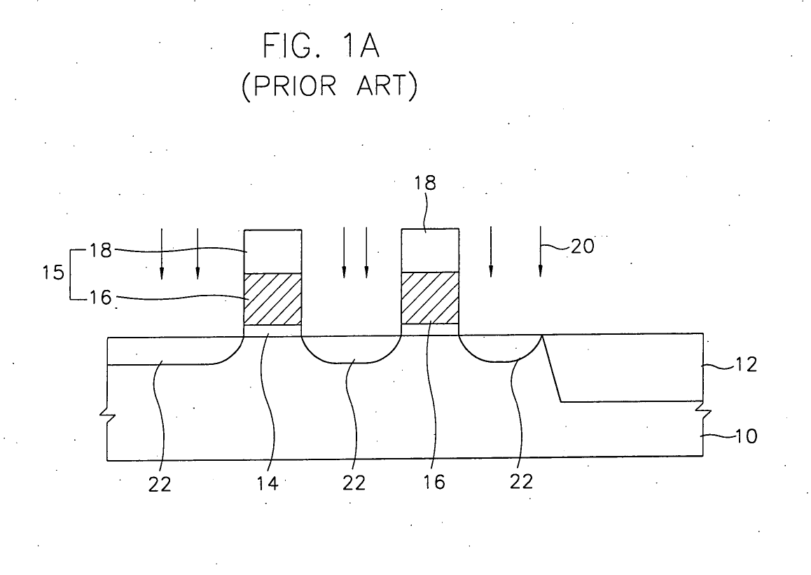

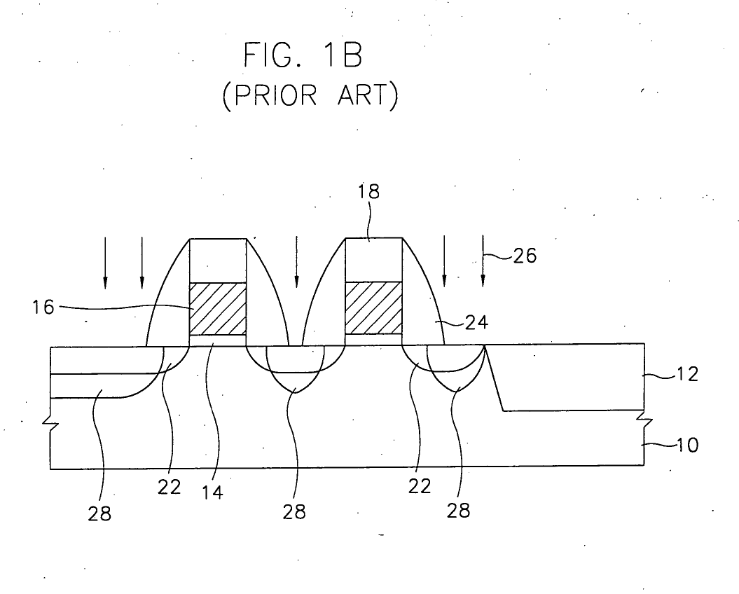

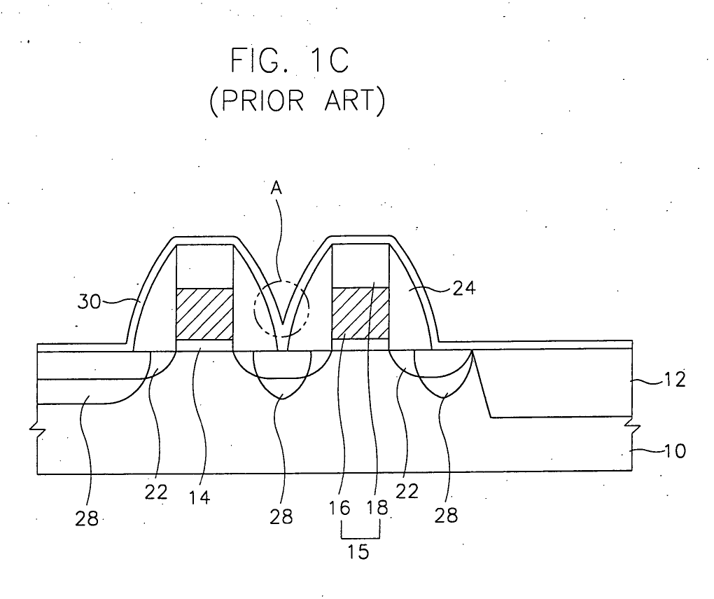

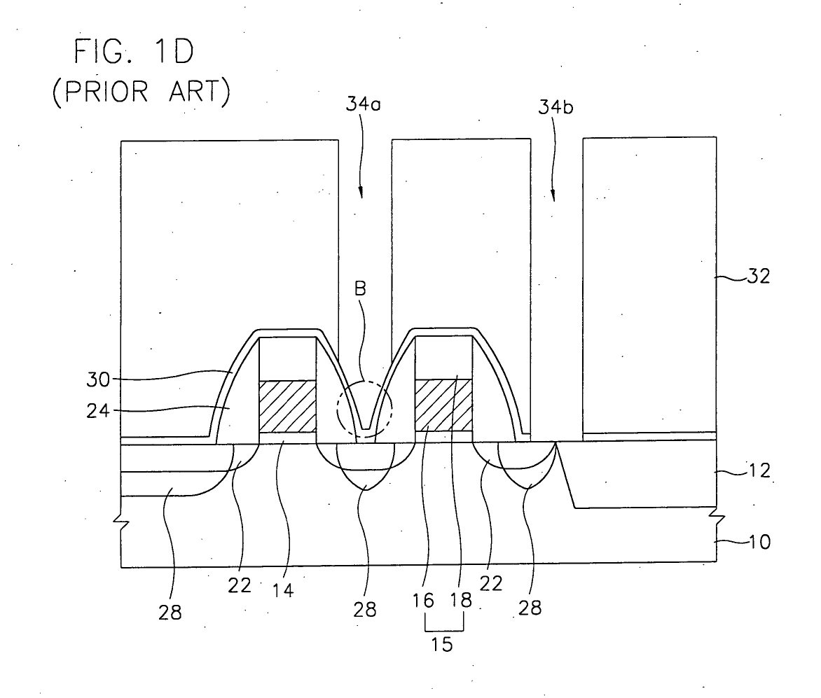

A conventional semiconductor device, such as the device of FIG. 1, has a narrow width between the gate electrodes 15, to which the contact hole is formed, by the LDD spacers 24 formed on the sidewalls of the gate electrode 15. When the etch-stopping layer 30 is deposited to facilitate the borderless contact process, the narrow space between the gate electrodes 15 is filled with the etch-stopping layer 30. Thus, the etch-stopping layer 30 remains between the gate electrodes 15 during the following contact hole etching process, so that the failure, such as the formation of the unopened portion (Refer “B” in FIG. 1D) of the first contract hole 34a, is occurred.

On the contrary, a semiconductor device according to the present invention has an enlarged width between the gate electrodes 109, the LDD spacers 118 formed on the sidewalls of the gate electrode 109 are removed after the source/drain ion-implantation process 120 is performed. Thus, since an etch-stopping layer 124 is deposited along a topology between the gate electrodes 109 prior to the borderless contact process, the thickness of the etch-stopping layer 124 formed on the field oxide layer 102 and the thickness of the etch-stopping layer 124 formed between the gate electrodes 109 are uniform. Therefore, the bottom critical dimension of the contact hole formed between the gate electrodes 109 can be sufficiently achieved, thereby preventing the formation of an unopened portion of a contact hole.

Referring to FIG. 2G, after removing the spacers 118, the etch-stopping layer 124 is formed by depositing a nitride film such as silicon nitride (SiN) on the entire surfaces of the gate electrode 109 and the semiconductor substrate 100 to a thickness in the range of about 100 to about 1000 Å, preferably, less than 200 Å.

When a borderless contact hole is formed from the surface of the semiconductor substrate 100 adjacent to the field oxide layer 102 to a portion of the surface of the field oxide layer 102 by etching an insulating interlayer (which will be formed on the etch-stopping layer 124 in a subsequent process), the etch-stopping layer 124 prevents a portion of the field oxide layer 102 comprising a material similar to a material of the insulating interlayer from being etched together with the insulating interlayer.

In a conventional semiconductor device, such as the device of FIG. 1, the etch-stopping layer 30 has a thickness greater than 500 Å to prevent the recess from being created on the field oxide layer 12 during the contact hole etching process. On the contrary, according to the preferred embodiment, the etch-protecting layer 116 remaining on the upper surface and the side surface of the gate electrode 109 is formed by using nitride similar to the etch-stopping layer 124. Therefore, the etch-protecting layer 116 prevents the filed oxide layer 102 from being etched during the following contact hole etching process. Accordingly, the field oxide layer 102 can be prevented from being etched even when the thickness of the etch-stopping layer 124 is formed less than 200 Å in consideration of the thickness of the etch-protecting layer 116.

Referring to FIG. 2H, an oxide film, such as BPSG (Boro-PhosphoSilicate glass) film or PSG (Phosphosilicate glass) film, is formed on the etch-stopping layer 124 to a thickness in the range of about 3000 to about 10000 Å by a plasma enhanced chemical vapor deposition (PECVD) method, thereby forming the insulating interlayer 126. An etch-back process or a CMP process may be performed to planarize the surface of the insulating interlayer 126.

Referring to FIG. 2I, a photoresist pattern (not shown) for defining a contact hole area is formed on the insulating interlayer 126 through a photo process. By using the photoresist pattern as an etching mask, the insulating interlayer 126 is dry-etched with a mixing gas in which the etch selectivity of the insulating interlayer 126 comprising oxide with respect to the etch-stopping layer 124 comprising nitride is 10-15:1. Then, the photoresist pattern is removed. The exposed etch-stopping layer 124, the etch-protecting layer 116 formed below the etch-stopping layer 124 and the buffer layer 114 are dry-etched by using the insulating interlayer 126 as an etching mask.

As a result, a first contact hole 128a for exposing the surface of the semiconductor substrate 100 between the gate electrodes 109 and a second contact hole 128b for the borderless contact between the active area and the field area are formed. The second contact hole 128b exposes the surface of the semiconductor substrate 100 adjacent to the field oxide layer 102 and a portion of the surface of the field oxide layer 102.

According to a preferred embodiment, the spacers 118 formed on the sidewalls of the gate electrode 109 in order to achieve the LDD structure are removed after implanting the highly doped source/drain ion, so the width between the gate electrodes 109 can be sufficiently obtained.

Further, the etch-stopping layer 124 for the borderless contact process is formed so that the thickness of the etch-stopping layer 124 formed on the field oxide layer 102 and the thickness of the etch-stopping layer 124 formed between the gate electrodes 109 are uniformly maintained. Therefore, the etch-stopping layer 124 deposited between gate electrodes 109 can be completely removed, thereby preventing the formation of the conventional unopened portion of a contact hole.

Moreover, since the etch-protecting layer 116 remaining on the upper and side surfaces of the gate electrode 109 comprises nitride similar to a material of the etch-stopping layer 124, the field oxide layer 102 can be prevented from being etched even when the thickness of the etch-stopping layer 124 is no more than 200 Å in considering with the thickness of the etch-protecting layer 116.

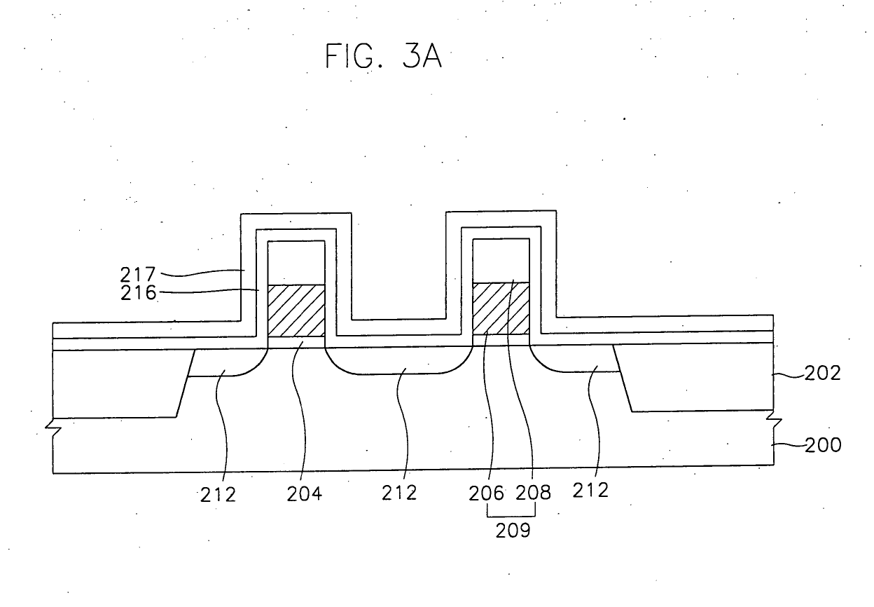

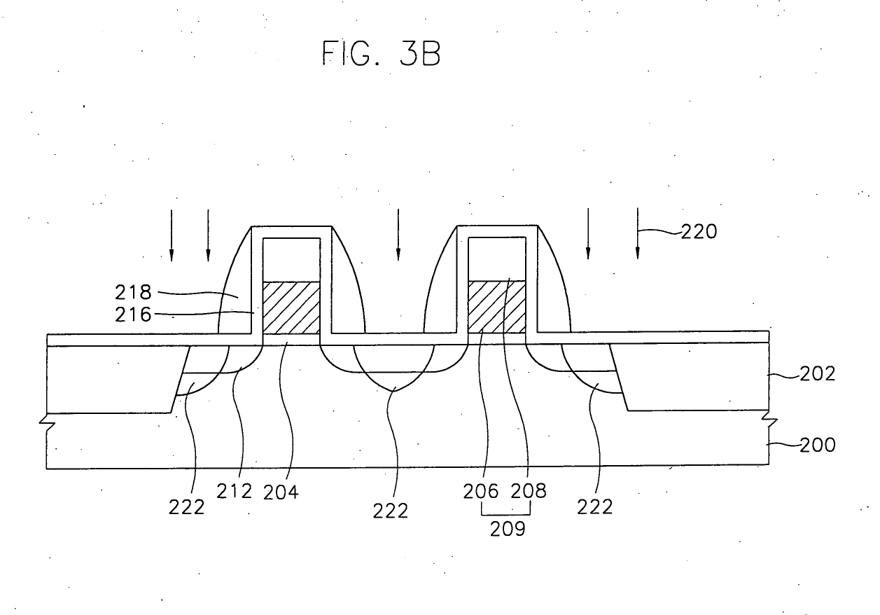

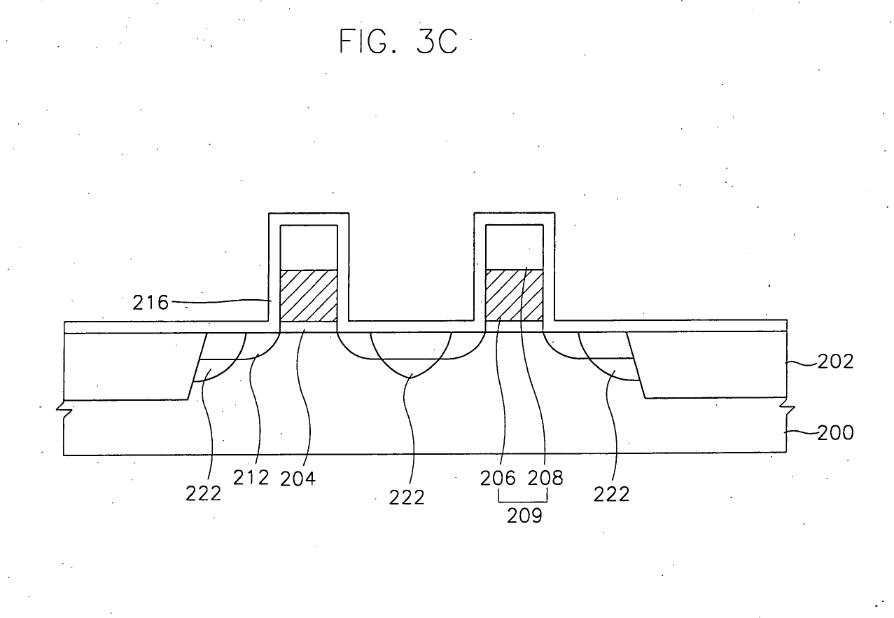

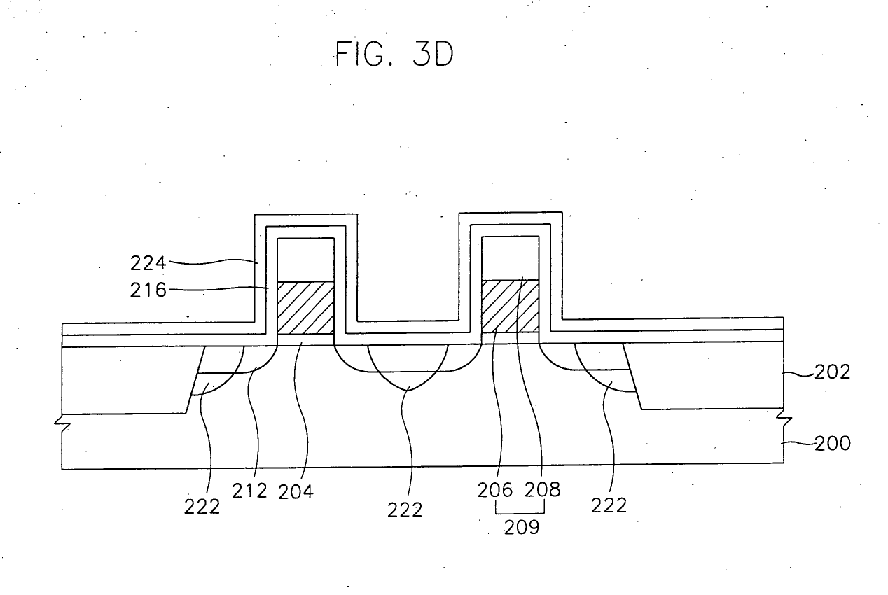

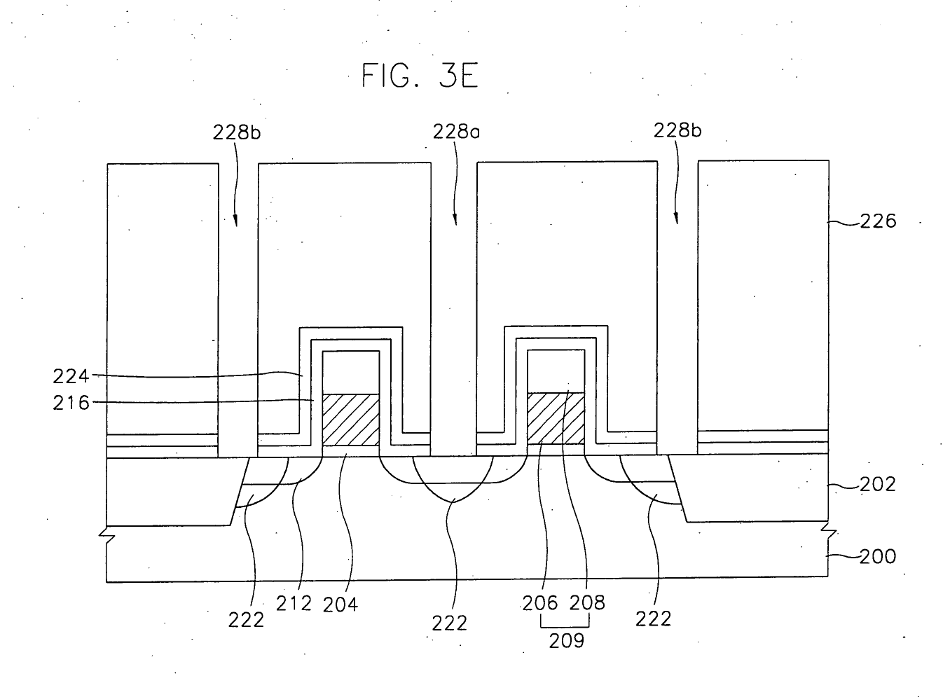

FIGS. 3A to 3F are sectional views showing a method for forming a contact hole of the semiconductor device according to another embodiment of the present invention.

Referring to FIG. 3A, a field oxide layer 202 is formed on a semiconductor substrate 200 through an isolation process, such as a shallow trench isolation process, to thereby divide the semiconductor substrate 200 into an active area and a field area. Then, a gate oxide layer 204 and a gate electrode 209 are formed on the active area of the semiconductor substrate 200. Preferably, the gate electrode 209 comprises a polycide structure comprising of a polysilicon layer 206 doped with impurities and a metal silicide layer 208 stacked on the polysilicon layer 206.

A first impurity is ion-implanted by using the gate electrode 209 as a mask, so that lightly doped source/drain areas 212 (that is LDD areas) are formed in the surface of the semiconductor substrate 200 on both sides of the gate electrode 209. A heat-treatment process is performed to activate the implanted ions and simultaneously, to compensate lattice defects of the semiconductor substrate 200 caused by the above ion-implantation.

An oxide film such as silicon oxide (SiO₂) film is deposited to a thickness in the range of about 50 to about 300 Å on the entire surface of the semiconductor substrate 200 in which the gate electrode 209 and the lightly doped source/drain areas 212 are formed, thereby forming an etch-protecting layer 216. The etch-protecting layer 216 prevents the gate electrode 109, the semiconductor substrate 200 and the field oxide layer 202 from being damaged during a following LDD spacer removing process.

An insulating layer 217 comprising a material having an etch selectivity to a material forming the etch-protecting layer 216 with respect to an any etching process, is formed on the etch-protecting layer 216 to a thickness in the range of about 500 to about 800 Å. Preferably, the insulating layer 217 comprises polysilicon.

Referring to FIG. 3B, a spacer 218 comprising polysilicon is formed on both sidewalls of the gate electrode 209 by performing an etch-back process with respect to the insulating layer 217. Then, a second impurity 220 is ion-implanted by using the spacers 218 and the gate electrode 209 as a mask, thereby forming highly doped source/drain areas 222 in the surface of the semiconductor substrate 200 on both sides of the spacers 218.

According to a preferred embodiment, since the etch-protecting layer 216 formed on the semiconductor substrate 200 comprises oxide, the deterioration in characteristics of the transistor caused by the blocking effect of the ion implantation process 220 can be prevented during the implantation of the source/drain ion.

A heat-treatment process is performed to activate the implanted ions and simultaneously, to compensate lattice defects of the semiconductor substrate 200 caused by the ion-implantation.

Referring to FIG. 3C, after forming the highly doped source/drain areas 222, a wet etching process is performed by using an etchant in which an etch selectivity of polysilicon with respect to oxide is about 30:1, thereby removing only the spacers 218. The etch-protecting layer 216 prevents the gate electrode 209, the active area of the semiconductor substrate 200 and the field oxide layer 202 from being damaged during the wet etching process. When the spacers 218 are removed, only the etch-protecting layer 216 remains on the upper surface and the side surface of the gate electrode 209 in a uniform thickness.

By removing the spacers 218, the width between the gate electrodes 209 is enlarged, so the bottom critical dimension of a contact hole formed between the gate electrodes 209 can be sufficiently achieved.

Referring to FIG. 3D, after removing the spacers 218, a nitride film such as silicon nitride (SiN) film is deposited on the entire surfaces of the gate electrode 209 and the semiconductor substrate 200 to a thickness greater than 300 Å, thereby forming an etch-stopping layer 224.

When a borderless contact hole is formed from the surface of the semiconductor substrate 200 adjacent to the field oxide layer 202 to a portion of the surface of the field oxide layer 202 by etching an insulating interlayer (which will be formed on the etch-stopping layer 224 in a subsequent process), the etch-stopping layer 224 prevents the portion of the field oxide layer 202 comprised of a material similar to a material of the insulating interlayer from being etched together with the insulating interlayer.

Since the etch-protecting layer 216 remaining below the etch-stopping layer 224 comprises oxide, in a preferred embodiment, the etch-stopping layer 224 needs to have a thickness greater than 300 Å to sufficiently prevent a recess from being created on the field oxide layer 202.

Referring to FIG. 3E, an oxide film such as BPSG (Boro-PhosphoSilicate glass) film or PSG (PhosphoSilicate glass) film is formed on the etch-stopping layer 224 to a thickness in the range of about 3000 to about 10000 Å by performing the plasma enhanced chemical vapor deposition (PECVD) process, thereby forming the insulating interlayer 226. At this time, an etch-back process or a CMP process may be performed to planarize the surface of the insulating interlayer 226.

A photoresist pattern (not shown) for defining a region of a contact hole is formed on the insulating interlayer 226 through a photo process. By using the photoresist pattern as an etching mask, the insulating interlayer 226 is dry-etched with a mixing gas in which the etch selectivity of the insulating interlayer 226 comprising oxide with respect to the etch stopping layer 224 comprising nitride is about 10-15:1. Thereafter, the photoresist pattern is removed. The exposed etch-stopping layer 224 and the etch-protecting layer 216 formed below the etch-stopping layer 224 are dry-etched by using the insulating interlayer 226 as an etching mask.

As a result, a first contact hole 228a for exposing the surface of the semiconductor substrate 200 between the gate electrodes 209 and a second contact hole 228b for the borderless contact between the active area and the field area. The second contact hole 228b exposes the surface of the semiconductor substrate 200 adjacent to the field oxide layer 202 and a portion of the surface of the field oxide layer 202.

According to a preferred embodiment, the etch-protecting layer 216 provided for removing the LDD spacers 218 is formed by using oxide such as silicon oxide (SiO₂), so the blocking effect of the source/drain ion implantation process is prevented and the electrical characteristics of the transistor are improved.

According to preferred embodiments of the present invention, spacers are formed to achieve a LDD structure on the sidewalls of a gate electrode formed in the semiconductor substrate, and then source/drain areas are formed using the spacers. A contact hole area between the gate electrodes is secured by removing the spacers, and an etch-stopping layer and an insulating interlayer are sequentially formed on the resultant structure for protecting a field oxide layer when a borderless contact process is performed. Then, the etch-stopping layer and the insulating interlayer are etched so as to form the contact hole.

Thus, the thickness of the etch-stopping layer formed between the gate electrodes is advantageously less than the thickness of the etch-stopping layer formed on the field oxide layer, thereby preventing the formation an unopened contact hole during the etching process of the etch-stopping layer.

While the present invention has been described in detail with reference to the preferred embodiments thereof, it should be understood to those skilled in the art that various changes, substitutions and alterations can be made hereto without departing from the scope of the invention as defined by the appended claims.

1-10. (Cancelled)

11. A method for forming a contact hole of a semiconductor device, the method comprising the steps of:
forming a plurality of gate electrodes on an active area of a semiconductor substrate, the semiconductor substrate comprising the active area and a field area divided by a field oxide layer;
forming an etch-protecting layer on the gate electrodes and the semiconductor substrate;
forming spacers on the etch-protecting layer formed on both sides of each gate electrode, the spacers comprising a material having an etch selectively with respect to the etch-protecting layer;
performing a source and drain ion-implantation process by using the gate electrodes on which the spares are formed as a mask;
removing the spacers;
forming an etch-stopping layer on the entire surface of the resultant structure;
forming an insulating interlayer on the etch-stopping layer; and
sequentially etching the insulating interlayer, the etch-stopping layer and the etch-protecting layer such that a first contact hole is formed to expose a surface of the semiconductor substrate between the gate electrodes and a second contact hole is formed to expose a surface of the semiconductor substrate adjacent to the field oxide layer and a portion of a surface of the field oxide layer, thereby forming a borderless contact between the field area and the active area.

12. The method of claim 11, wherein the step of forming the insulating interlayer comprises the step of forming the insulating interlayer with a material similar to a material of the etch-stopping to prevent formation of a recess on the filed oxide layer.

13. The method of claim 11, wherein the step of forming the etch-stopping layer comprises the step of forming the etch-stopping layer such that a thickness of the etch-stopping layer formed on the field oxide layer and a thickness of the etch-stopping layer formed between the gate electrodes are uniform.

14. The method of claim 11, wherein the etch-protecting layer comprises an oxide and the spacers comprises polysilicon.

15. The method of claim 14, wherein the step of removing the spacers comprising the step of performing a wet etching process using etchant in which an etch selectivity of the polysilicon with respect to the oxide is about 30:1.

16. The method of claim 14, wherein the etch-protecting layer has a thickness in the range of about 50 to about 300 Å.

17. The method of claim 11, wherein the step of forming the etch-stopping layer comprises the step of depositing a nitride to a thickness greater than 300 Å.

18. A method for forming a contact hole of a semiconductor device, the method comprising the steps of:
forming a plurality of gate electrodes on an active area of a semiconductor substrate, the semiconductor substrate comprising the active area and a field area divided by a field oxide layer;
forming an etch-protecting layer on the gate electrodes and the semiconductor substrate;
forming spacers on the etch-protecting layer formed on both sides of each gate electrode, the spacers comprising a material having an etch selectivity with respect to the etch-protecting layer;
performing a source and drain ion-implantation process by using the gate electrodes on which the spares are formed as a mask;
removing the spacers;
forming an etch-stopping layer on the entire surface of the resultant structure, wherein the etch-stopping layer comprising a material similar to a material of the etch-protecting layer;
forming an insulating interlayer on the etch-stopping layer; and
sequentially etching the insulating interlayer, the etch-stopping layer and the etch-protecting layer, such that a first contact hole is formed to expose a surface of the semiconductor substrate between the gate electrodes and a second contact hole is formed to expose a surface of the semiconductor substrate adjacent to the field oxide layer and a portion of a surface of the field oxide layer, thereby forming a borderless contact between the field area and the active area.

19. The method of claim 18, further comprising the step of performing an ion-implantation using the gate electrodes as a mask to form lightly doped source and drain areas before the step of forming the etch-protecting layer.

20. The method of claim 18, wherein the step of forming the etch-protecting layer comprises the step of depositing a nitride on the gate electrodes and the semiconductor substrate and the step of forming the spacers comprise the step of depositing an oxide on the etch-protecting layer.

21. The method of claim 20, wherein the nitride comprises one of SiN, SiON, and BN.

22. The method of claim 20, wherein the step of removing the spacers comprises the step of performing a wet etching process using etchant in which an etch selectivity of the oxide of the spacers with respect to the nitride of the etch-protecting layer is about 20:1.

23. The method of claim 20, wherein the step of forming the etch-protecting layer comprises the step of forming the etch-protecting layer to have a thickness capable of reducing a blocking effect of the step of performing the source/drain ion-implantation process.

24. The method of claim 23, wherein the etch-protecting layer has a thickness in the range of about 50 to about 300 Å.

25. The method of claim 18, wherein the step of forming the etch-stopping layer comprises the step of forming the etch-stopping layer to have a thickness in the range of about 100 to about 1000 Å.

26. The method of claim 20, further comprising the step of depositing an oxide on the gate electrodes and the semiconductor substrate to form a buffer layer before the step of depositing the nitride to form the etch-protecting layer.

27. The method of claim 26, wherein the buffer layer has a thickness in the range of about 30 to about 100 Å.
